(19) United States
(12) Patent Application Publication
(10) Pub. No.: US 2017/0018700 A1
(43) Pub. Date: Jan. 19, 2017

(54) PIEZOELECTRIC POLYMER COMPOSITE

(71) Applicant: FUJIFILM Corporation, Tokyo (JP)

(72) Inventors: Tetsu MIYOSHI, Ashigara-kami-gun (JP); Yosuke TAKEUCHI, Ashigara-kami-gun (JP)

(73) Assignee: FUJIFILM Corporation, Tokyo (JP)

(21) Appl. No.: 15/277,098

(22) Filed: Sep. 27, 2016

Related U.S. Application Data
(63) Continuation of application No. PCT/JP2015/059109, filed on Mar. 25, 2015.

(30) Foreign Application Priority Data
Mar. 28, 2014 (JP) 2014-070311

(51) Int. Cl. H01L 41/18

(52) U.S. Cl. CPC H01L 41/183; H04R 17/005

(57) ABSTRACT

In a piezoelectric polymer composite in which piezoelectric particles are dispersed in a polymer matrix, the piezoelectric particles include 5 vol % to 30 vol % of particles having a particle size which is 0.25 times to 1 time a thickness of the piezoelectric polymer composite. As a result, the piezoelectric polymer composite exhibits satisfactory piezoelectric characteristics.

### CROSS-REFERENCE TO RELATED APPLICATIONS

This application is a Continuation of PCT International Application No. PCT/JP2015/059109 filed on Mar. 25, 2015, which claims priority under 35 U.S.C. §119(a) to Japanese Patent Application No. 2014-070311 filed on Mar. 28, 2014. The above application is hereby expressly incorporated by reference, in its entirety, into the present application.

### BACKGROUND OF THE INVENTION

1. Field of the Invention

The present invention relates to a piezoelectric polymer composite which is used in, for example, an electroacoustic converter film of a speaker, a microphone, or the like.

2. Description of the Related Art

The development of a flexible display using a flexible substrate formed of a plastic or the like, for example, an organic EL display has been progressing.

In a case where this flexible display is used as an image display apparatus-cum-sound generation apparatus such as a television receiver that reproduces an image and a sound at the same time, a speaker which is an acoustic device for generating a sound is necessary.

Here, regarding the shape of a speaker in the related art, for example, a so-called cone speaker having a funnel shape or a dome speaker having a spherical shape is generally used. However, when this speaker is built into the above-described flexible display, lightweight properties and flexibility, which are advantageous effects of the flexible display, may deteriorate. In addition, in a case where the speaker is installed externally, for example, it is inconvenient to carry the speaker, and it is difficult to install the display on a curved wall, which may make the external appearance aesthetically unpleasant.

Under these circumstances, for example, JP2008-294493A discloses that a sheet-shaped flexible piezoelectric film is adopted as a speaker which can be integrated into a flexible display without deterioration in lightweight properties and flexibility.

The piezoelectric film is obtained by performing polarization processing on a uniaxially stretched polyvinylidene fluoride (PVDF) film at a high voltage, and thus has properties of expanding and contracting in response to an applied voltage.

Here, in a case where a flexible display having a rectangular shape in a plan view, into which a speaker formed of the piezoelectric film is integrated, is gripped and used as a portable apparatus in a gently bent state as with documents such as a newspaper or a magazine while changing its screen between portrait and landscape modes, it is preferable that the image display surface is bendable not only in the vertical direction but also in the horizontal direction.

However, since a uniaxially stretched PVDF piezoelectric film has in-plane anisotropy in its piezoelectric characteristics, the sound quality varies significantly depending on the bending direction even at the same curvature.

On the other hand, examples of a sheet-shaped flexible piezoelectric material having no in-plane anisotropy in its piezoelectric characteristics include a piezoelectric polymer composite in which piezoelectric particles are dispersed in a polymer matrix.

For example, “Toyoki KITAYAMA, Showa 46′ Journal of National Convention of The Institute of Electronics, Information and Communication Engineers, 366 (1971)” discloses a piezoelectric polymer composite in which the flexibility of PVDF and satisfactory piezoelectric characteristics of a PZT ceramic are realized at the same time, the piezoelectric polymer composite being obtained by mixing, PZT ceramic powder, which is a piezoelectric material, with PVDF by solvent casting or hot kneading.

Here, in the piezoelectric polymer composite, in order to improve piezoelectric characteristics, that is, the transmission efficiency of vibration energy, it is preferable to increase the proportion of the piezoelectric particles with respect to the matrix.

According to “Toyoki KITAYAMA, Showa 46′ Journal of National Convention of The Institute of Electronics, Information and Communication Engineers, 366 (1971)”, when the packing density of the piezoelectric particles is 50 vol % or higher, satisfactory piezoelectric characteristics can be obtained. On the other hand, it has been pointed out that, as the packing density increases excessively, the piezoelectric polymer composite becomes harder and more brittle.

As a method for solving this problem, WO2013/047875A discloses a piezoelectric polymer composite having a considerable frequency dispersion in elastic modulus in which a polymer material having viscoelasticity at room temperature is used as a matrix. In this piezoelectric polymer composite, high flexibility at 20 Hz or lower and high transmission efficiency of vibration energy in the audio frequency band (20 Hz to 20 kHz) can be realized at the same time.

By sandwiching the piezoelectric polymer composite between electrodes, an electroacoustic converter film having high flexibility and satisfactory piezoelectric characteristics which is suitable in, for example, a speaker for a flexible display can be manufactured.

### SUMMARY OF THE INVENTION

Recently, the demand for a reduction in the power consumption of electronic apparatuses has increased, and the development of a piezoelectric polymer composite having more satisfactory piezoelectric characteristics is desired.

However, the packing density of piezoelectric particles in an electroacoustic converter film disclosed in WO2013/047875A is 60 vol % which is substantially the closest packing, and further significant improvement in piezoelectric characteristics is difficult.

An object of the present invention is to solve the above-described problems of the related art and to provide a piezoelectric polymer composite in which piezoelectric particles are dispersed in a polymer matrix and in which the packing density of the piezoelectric particles and the transmission efficiency of vibration energy are improved and more satisfactory piezoelectric characteristics are exhibited.

In order to solve the above-described problems, according to the present invention, there is provided a piezoelectric polymer composite including: a matrix that is formed of a polymer material; and piezoelectric particles that are dispersed in the matrix.

In the piezoelectric polymer composite, the piezoelectric particles include 5 vol % to 30 vol % of particles having a particle size which is 0.25 times to 1 time a thickness of the piezoelectric polymer composite.

In the piezoelectric polymer composite according to the present invention, is preferable that a particle size distribution of the piezoelectric particles has a maximum value at a particle size in a range from a median size (D50) to the thickness of the piezoelectric polymer composite.

In addition, it is preferable that an amount of particles having a particle size of 1 μm or less in the piezoelectric particles is 10 vol % or lower.

In addition, it is preferable that the median size (D50) of the piezoelectric particles is (1+the thickness of the piezoelectric polymer composite×0.05) to (1+the thickness of the piezoelectric polymer composite×0.3).

In addition, it is preferable that the piezoelectric particles are lead zirconate titanate particles.

Further, it is preferable that the matrix is formed of a polymer material having viscoelasticity at normal temperature.

In the piezoelectric polymer composite according to the present invention in which piezoelectric particles are dispersed in a polymer matrix, the packing density of the piezoelectric particles and the transmission efficiency of vibration energy of the piezoelectric particles can be improved.

Therefore, in the piezoelectric polymer composite according to the present invention, more satisfactory piezoelectric characteristics can be obtained as compared to a piezoelectric polymer composite of the related art.

### BRIEF DESCRIPTION OF THE DRAWINGS

FIG. 1 is a diagram schematically showing an example of a piezoelectric polymer composite according to the present invention.

FIG. 2 is a graph showing an example of a particle size distribution of the piezoelectric polymer composite according to the present invention.

FIGS. 3A and 3B are diagrams showing an example of an electroacoustic converter film using the piezoelectric polymer composite according to the present invention.

### DESCRIPTION OF THE PREFERRED EMBODIMENTS

Hereinafter, a piezoelectric polymer composite according to the present invention will be described in detail based on a preferable embodiment shown in the accompanying drawings.

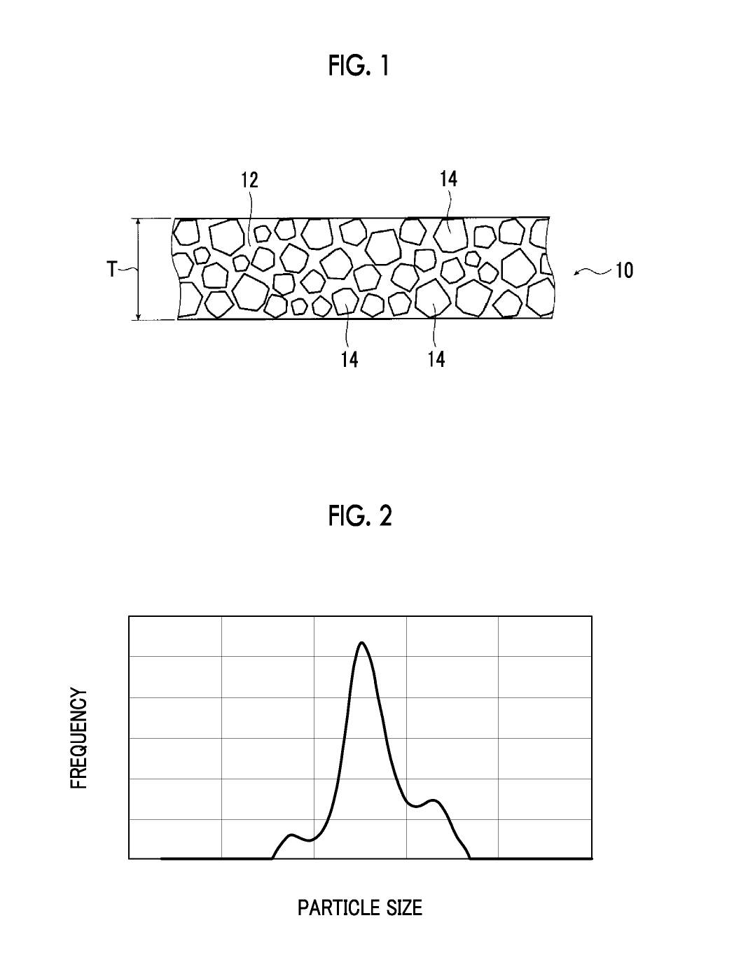

FIG. 1 schematically shows an example of the piezoelectric polymer composite according to the present invention.

As shown in FIG. 1, a piezoelectric polymer composite 10 according to the present invention has a configuration in which piezoelectric particles 14 are dispersed in a matrix 12 formed of a polymer material. Hereinafter, the piezoelectric polymer composite 10 according to the present invention will also be referred to simply as “piezoelectric composite 10”.

In the piezoelectric composite 10 according to the present invention, the piezoelectric particles 14 may be dispersed regularly or irregularly in the matrix 12 as long as they are uniformly dispersed therein.

In the piezoelectric composite 10 according to the present invention, as the piezoelectric particles 14, particles of various piezoelectric materials exhibiting piezoelectric characteristics can be used.

The piezoelectric particles 14 are ceramic particles having a perovskite crystal structure or a wurtzite crystal structure. Preferable examples of the ceramic particles constituting the piezoelectric particles 14 include particles of lead zirconate titanate (PZT), lead lanthanum zirconate titanate (PLZT), barium titanate (BaTiO₃), zinc oxide (ZnO), a solid solution (BFBT) of barium titanate and bismuth ferrite (BiFe₃), and the like.

Among these, PZT particles are more preferably used from the viewpoint of obtaining the piezoelectric composite 10 having satisfactory piezoelectric characteristics.

In the piezoelectric composite 10 according to the present invention, the piezoelectric particles 14 include 5 vol % to 30 vol % of particles having a particle size which is 0.25 times to 1 time a thickness T of the piezoelectric composite 10. Hereinafter, the thickness T of the piezoelectric composite 10 will also be referred to simply as “thickness T”.

In other words, in the piezoelectric composite 10 according to the present invention, the proportion (content) of the particles having a particle size of “(Thickness T×0.25) to (Thickness T)” is 5 vol % to 30 vol % with respect to the piezoelectric particle 14.

By using the piezoelectric particles 14 having the above-described particle size distribution, the piezoelectric composite 10 according to the present invention has more satisfactory piezoelectric characteristics than a piezoelectric polymer composite of the related art.

The particle size of the piezoelectric particles 14 may be measured using, for example, a laser scattering particle size analyzer.

In the piezoelectric composite 10 in which the piezoelectric particles 14 are dispersed in the matrix 12, in order to obtain satisfactory piezoelectric characteristics, it is necessary to increase the transmission efficiency of vibration energy of the piezoelectric particles 14. In order to obtain high transmission efficiency of vibration energy, it is preferable that the particle size of the piezoelectric particles 14 is large. In particular, by adding the particles having a particle size which is 0.25 times to 1 time the thickness T of the piezoelectric composite 10, the transmission efficiency of vibration energy of the piezoelectric particles 14 can be increased.

On the other hand, in the piezoelectric composite 10, in order to obtain satisfactory piezoelectric characteristics, it is necessary to increase the packing density of the piezoelectric particles 14 in the piezoelectric composite 10 to some extent.

However, in a case where only coarse piezoelectric particles 14 are used, the packing density of the piezoelectric particles 14 in the piezoelectric composite 10 cannot be sufficiently increased.

On the other hand, in the piezoelectric composite 10 according to the present invention, the piezoelectric particles 14 include 5 vol % to 30 vol % of particles having a particle size which is 0.25 times to 1 time the thickness T. That is, the piezoelectric particles 14 include 5 vol % to 30 vol % of particles having a particle size of 0.251 to T.

With the above-described configuration, high transmission efficiency of vibration energy can be realized by coarse piezoelectric particles 14 having a particle size which is 0.25 times to 1 time the thickness T; and the packing density of the piezoelectric particles 14 in the piezoelectric composite 10 can be increased by fine piezoelectric particles 14 having a smaller particle size than the coarse piezoelectric particles 14 entering into gaps between the coarse piezoelectric particles 14.

Therefore, the piezoelectric composite 10 according to the present invention can exhibit satisfactory piezoelectric characteristics due to a synergistic effect of high packing density of the piezoelectric particles 14 and high transmission efficiency of vibration energy. In addition, more satisfactory piezoelectric characteristics can be obtained as compared to a piezoelectric polymer composite of the related art having the same packing density.

In a case where the amount of the piezoelectric particles 14 having a particle size which is 0.25 times to 1 times the thickness T is lower than 5 vol % in the piezoelectric composite 10 according to the present invention, there are problems in that, for example, sufficient piezoelectric characteristics cannot be obtained due to low transmission efficiency of vibration energy.

In a case where the amount of the piezoelectric particles 14 having a particle size which is 0.25 times to 1 times the thickness T is higher than 30 vol %, there are problems in that, for example, a sufficient packing density of the piezoelectric particles 14 cannot be obtained and piezoelectric characteristics deteriorate.

In consideration of the above-described points, it is preferable that the amount of the piezoelectric particles 14 having a particle size, which is 0.25 times to 1 time the thickness T, in the piezoelectric composite 10 according to the present invention is 10 vol % to 30 vol %.

In the piezoelectric composite 10 according to the present invention, it is preferable that a particle size distribution of the piezoelectric particles 14 has a maximum value (peak/shoulder) at a particle size in a range from a median size (D50 (d50)) to the thickness T.

That is, in the piezoelectric composite 10 according to the present invention, it is preferable that, for example, as schematically shown in FIG. 2, the particle size distribution of the piezoelectric particles 14 has another maximum value on a side where the particle size is more than that at the largest maximum value.

With the above-described configuration, the characteristics of the piezoelectric composite 10 according to the present invention become more significant by the fine piezoelectric particles 14 entering into gaps between the coarse particles 14 having a particle size which is 0.25 times to 1 time the thickness T.

Therefore, the above-described configuration is preferable from the viewpoint of for example, obtaining more satisfactory piezoelectric characteristics.

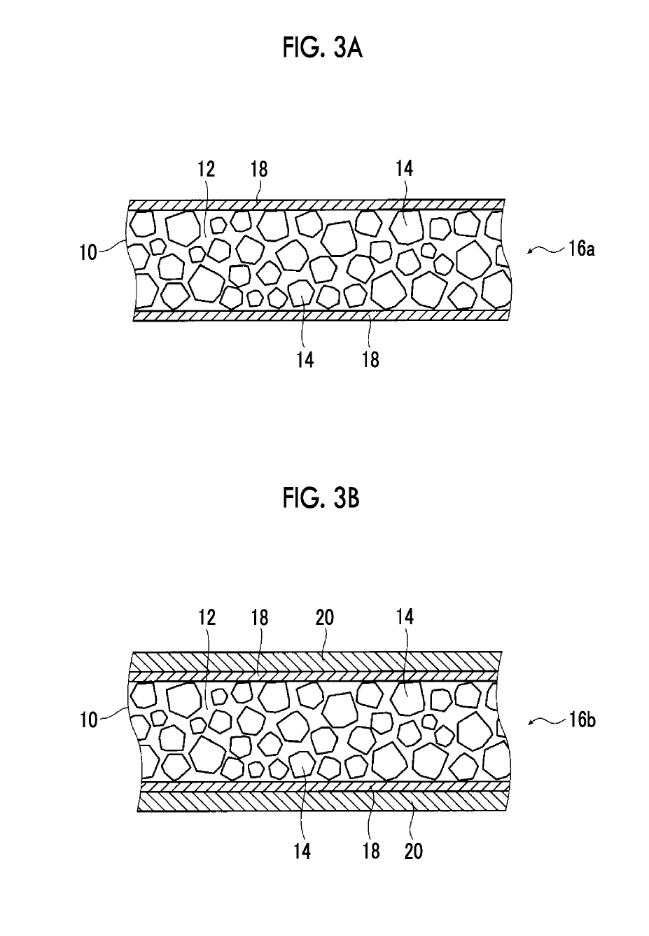

In an electroacoustic converter film described below (refer to FIGS. 3A and 3B) which is obtained in a case where a maximum value is present at a particle size position of more than the thickness T of the piezoelectric composite 10, adhesiveness between the electroacoustic converter film and an electrode layer deteriorates, and there may be a problem in that, for example, conversion characteristics deteriorate. In particular, adhesiveness between the electroacoustic converter film and an electrode layer on a side where a paint obtained by dispersing the piezoelectric particles in a polymer material and an organic solvent is not applied deteriorates.

Therefore, it is preferable that the particle size distribution of the piezoelectric particles 14 has a maximum value in a range of the median size (D50) to the thickness T of the piezoelectric composite 10.

In the piezoelectric composite 10 according to the present invention, it is preferable that the median size (D50) of piezoelectric particles 14 is (1+the thickness T×0.05) μm to (1+the thickness T×0.3) μm. That is, it is preferable that the median size (D50) of piezoelectric particles 14 is (1+0.05T) μm to (1+0.3T) μm.

The above-described configuration is preferable from the viewpoint that, for example, satisfactory piezoelectric characteristics and high flexibility can be realized such that a uniform and dense piezoelectric composite can be manufactured.

In addition, from this point of view, it is preferable that the median size (D50) of piezoelectric particles 14 is (1+0.05T) μm to (1+0.25T) μm.

In the piezoelectric composite 10 according to the present invention, the particle size of the piezoelectric particles 14 can be appropriately selected according to the size and use of the piezoelectric composite 10 as long as it satisfies the condition that the amount of the piezoelectric particles 14 having a particle size, which is 0.25 times to 1 time the thickness T, is 5 vol % to 30 vol % with respect to the total amount of all the piezoelectric particles 14.

However, it is preferable that the particle size of the piezoelectric particles 14 is the thickness T or less. As described above, when an electroacoustic converter film is obtained in a case where the particle size of the piezoelectric particles 14 is more than the thickness T, adhesiveness between the electroacoustic converter film and an electrode layer deteriorates, and there may be a problem in that, for example, conversion characteristics deteriorate.

As described above, in the piezoelectric composite 10 according to the present invention, the amount of the piezoelectric particles 14 having a particle size, which is 0.25 times to 1 time the thickness T, is 5 vol % to 30 vol % with respect to the total amount of all the piezoelectric particles 14. As a result, the fine particles are filled with gaps between the coarse particles, and the packing density of the piezoelectric particles 14 in thee piezoelectric composite 10 can be improved.

However, particles having a particle size of 1 μm or less are likely to aggregate, and it is difficult to uniformly disperse the piezoelectric particles 14 in the matrix 12. Accordingly, it is preferable that the amount of particles having a particle size of 1 μm or less is small. Therefore, it is preferable that the amount of the piezoelectric particles 14 having a particle size of 1 μm or less is 10 vol % or lower with respect to the total amount of all the piezoelectric particles 14.

In the piezoelectric composite 10 according to the present invention, as the matrix (polymer matrix) 12, various well-known polymer materials which are used in a piezoelectric polymer composite can be used.

Specific examples of the polymer materials include polyvinylidene fluoride (PVDF), cyanoethylated pullulan, and nylon.

In the piezoelectric composite 10 according to the present invention, it is more preferable that the matrix 12 is formed of a polymer material having viscoelasticity at normal temperature. “Normal temperature” described in this specification refers to a temperature range of about 0° C. to 50° C.

As described below, an electroacoustic converter film is obtained by providing an electrode layer on opposite surfaces of the piezoelectric composite 10 according to the present invention as shown in FIG. 3A, or further providing a protective layer on surfaces of the electrode layers as shown in FIG. 3B. This electroacoustic converter film is suitably used as, for example, a flexible speaker such as a speaker for a flexible display.

Here, it is preferable that the piezoelectric composite 10 used for the flexible speaker satisfies the following requirements.

(i) Flexibility

For example, in a case where the flexible speaker is gripped as a portable apparatus in a gently bent state as with documents such as a newspaper or a magazine, the flexible speaker continuously undergoes significant bending deformation at a relatively low frequency of several Hz or lower due to external conditions. At this time, when the piezoelectric polymer composite is hard, bending stress corresponding to the hardness is generated, and an interface between the polymer matrix and the piezoelectric particles cracks, which may lead to fracture. Accordingly, appropriate flexibility is required in the piezoelectric polymer composite. In addition, as strain energy can be diffused to the outside as heat, the stress can be relaxed. Accordingly, it is required that the loss tangent of the piezoelectric polymer composite is appropriately large.

(ii) Sound Quality

The speaker generates a sound by vibrating the piezoelectric particles at a frequency in the audio frequency band of 20 Hz to 20 kHz to vibrate the entire region of a vibration plate (piezoelectric polymer composite) using the vibration energy. Accordingly, in order to improve the transmission efficiency of vibration energy, the piezoelectric polymer composite requires an appropriate hardness. In addition, in a case where frequency characteristics of the speaker are smooth, when a minimum resonance frequency f₀ varies depending on a variation in curvature, a variation of sound quality also decreases. Accordingly, it is required that the loss tangent of the piezoelectric polymer composite is appropriately large.

Based on the above-described points, it is required that the piezoelectric composite 10 used in the flexible speaker is hard with respect to vibration at 20 Hz to 20 kHz and is flexible with respect to vibration at several Hz or lower. In addition, it is required that the loss tangent of the piezoelectric composite 10 is appropriately large with respect to vibration in all the frequencies of 20 kHz or lower.

In general, a polymer solid has a viscoelastic relaxation mechanism, and along with an increase in temperature or a decrease in frequency, a large-scale molecular motion is observed as a decrease (relaxation) in storage elastic modulus (Young's modulus) or a maximum value (absorption) of loss elastic modulus. In particular, relaxation caused by micro-Brownian motion of a molecular chain in an amorphous region is called primary dispersion and is observed as an extremely large relaxation. A temperature at which the primary dispersion occurs is a glass transition point (Tg), and the viscoelastic relaxation mechanism is most significant at this temperature.

In the piezoelectric composite 10, the polymer material having a glass transition point at normal temperature, in other words, the polymer material having viscoelasticity at normal temperature is used as the matrix 12. As a result, the piezoelectric composite 10 which is hard with respect to vibration at 20 Hz to 20 kHz and is flexible with respect to vibration of several Hz or lower can be realized. In particular, from the viewpoint of, for example, suitably exhibiting the hardness and the flexibility, it is preferable that a polymer material having a glass transition temperature at a frequency of 1 Hz at normal temperature is used as the matrix 12 of the piezoelectric composite 10.

As the polymer material having viscoelasticity at normal temperature, various well-known materials can be used. It is preferable that a polymer material has a maximum value of loss tangent Tan δ of 0.5 or higher at a frequency of 1 Hz at normal temperature in a dynamic viscoelasticity test.

As a result, when the piezoelectric composite 10 is gently bent by external force, stress concentration on an interface between the matrix 12 and the piezoelectric particles 14 in a maximum bending moment portion is relaxed, and high flexibility can be expected.

In addition, it is preferable that the storage elastic modulus (E′) of the polymer material at a frequency of 1 Hz in dynamic viscoelasticity measurement is 100 MPa or higher at 0° C. and is 10 MPa or lower at 50° C.

As a result, the bending moment generated when the piezoelectric composite 10 is gently bent by external force can be reduced, and concurrently, the piezoelectric composite 10 can be made to be hard with respect to acoustic vibration of 20 Hz to 20 kHz.

In addition, it is more preferable that the polymer material has a relative dielectric constant of 10 or higher at 25° C. As a result, when a voltage is applied to the piezoelectric polymer composite, a higher electric field is applied to the piezoelectric particles 14 in the matrix 12. Therefore, a large amount of deformation can be expected.

However, on the other hand, from the viewpoint of, for example, securing satisfactory moisture resistance, it is also preferable that the relative dielectric constant of the polymer material at 25° C. is 10 or lower.

Examples of the polymer material satisfying the above-described conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate. In addition, as the polymer material, a commercially available product such as HYBRAR 5127 (manufactured by Kuraray Co., Ltd.) can be preferably used.

Among these polymer materials, one kind may be used alone, or a combination (mixture) of plural kinds may be used.

The matrix 12 which is the polymer material having viscoelasticity at normal temperature is optionally used in combination with plural polymer materials.

That is, for example, in order to adjust dielectric characteristics or mechanical characteristics, optionally, not only a viscoelastic material such as cyanoethylated PVA but also other dielectric polymer materials are added to the matrix 12.

Examples of the dielectric polymer materials which can be added include: fluorine polymers such as polyvinylidene fluoride, vinylidene fluoride-tetrafluoroethylene copolymers, vinylidene fluoride-trifluoroethylene copolymers, polyvinylidene fluoride-trifluoroethylene copolymers, and polyvinylidene fluoride-tetrafluoroethylene copolymers; polymers having a cyano group or a cyanoethyl group such as vinylidene cyanide-vinyl acetate copolymers, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubbers such as nitrile rubber and chloroprene rubber.

Among these, a polymer material having a cyanoethyl group is preferably used.

As the dielectric polymer which is added to the matrix 12 of the piezoelectric composite 10 in addition to the material having viscoelasticity at normal temperature such as cyanoethylated PVA, one kind may be used alone, or plural kinds may be used.

In addition, in addition to the dielectric polymer material, a thermoplastic resin such as a vinyl chloride resin, polyethylene, polystyrene, a methacrylic resin, polybutene, or isobutylene; or a thermosetting resin such as a phenol resin, a urea resin, a melamine resin, an alkyd resin, or mica may be added in order to adjust the glass transition point (Tg).

Further, in order to improve viscosity, a viscosity imparting agent such as rosin ester, rosin, terpene, terpene phenol, or a petroleum resin may be added.

In the matrix 12 of the piezoelectric composite 10, the addition amount of polymers other than the viscoelastic material such as cyanoethylated PVA is not particularly limited, but the proportion thereof in the matrix 12 is preferably 30 mass % or lower.

As a result, the characteristics of the polymer material added can be exhibited without deterioration in the viscoelastic relaxation mechanism of the matrix 12. Therefore, the preferable results can be obtained from the viewpoint of, for example, obtaining high dielectric constant, improving heat resistance, and improving adhesiveness between the piezoelectric particles 14 and an electrode layer.

In the piezoelectric composite 10 according to the present invention, a ratio of the amounts of the matrix 12 and the piezoelectric particles 14 may be appropriately set according to the size of the piezoelectric composite 10, in particular, the size and thickness thereof in a plane direction, the use of the piezoelectric composite 10, the characteristics required for the piezoelectric composite 10, and the like.

The thickness of the piezoelectric composite 10 according to the present invention may be appropriately set according to the size of thee piezoelectric composite 10 in a plane direction, the use of the piezoelectric composite 10, the characteristics required for the piezoelectric composite 10, the materials of the matrix 12 and the piezoelectric particles 14 which form the piezoelectric composite 10, and the like.

Here, in consideration of the investigation by the present inventors, the thickness of the piezoelectric composite 10 is preferably 10 μm to 300 μm, more preferably 20 μm to 200 μm, and still more preferably 30 μm to 100 μm.

By adjusting the thickness of the piezoelectric composite 10 to be in the above-described range, the preferable results can be obtained from the viewpoints of, for example, securing rigidity and obtaining an appropriate flexibility.

The piezoelectric composite 10 can be prepared using the same method as that of a well-known piezoelectric polymer composite.

That is, the polymer material which is the matrix 12 is dissolved in an organic solvent to obtain a solution, the piezoelectric particles 14 are added and diffused in the solution, and the piezoelectric particles 14 are dispersed in the polymer material and the organic solvent to prepare a paint.

The organic solvent is not particularly limited, and various organic solvents such as dimethylformamide (DMF), methyl ethyl ketone, acetone, or cyclohexanone can be used.

Once the paint is prepared, the paint is applied to a sheet-like material, and the organic solvent is evaporated and dried to obtain the piezoelectric composite 10. Here, as the sheet-like material, an electrode layer 18 of an electroacoustic converter film described below and a laminate including the electrode layer 18 and a protective layer 20 of the electroacoustic converter film may be used.

A coating method of the paint is not particularly limited, and all of the well-known coating methods such as coating methods using a slide coater or a doctor coater can be used.

Once the piezoelectric composite 10 is prepared, it is preferable that polarization processing (polling) of the piezoelectric composite 10 is performed. The polarization processing of the piezoelectric composite 10 can be used using a well-known method.

In addition, before the polarization processing, calendering of smoothing a surface of the piezoelectric composite 10 using a heating roller or the like may be performed. By performing the calendering, a thermal pressure bonding step described below can be smoothly performed.

As a preferable method of the polarization processing, for example, the following method can be exemplified.

That is, the piezoelectric composite 10 is placed on a conductive sheet, or the electrode layer 18 is provided on a surface of the piezoelectric composite 10. Using a corona electrode having a wire shape or the like in one direction, a DC power supply is connected to the conductive sheet and the corona electrode.

Next, for example, in a state the piezoelectric composite 10 is heated and kept at a temperature of 100° C. using heating means, corona discharge is generated by applying a DC voltage of, for example, 6 kV between the DC power supply and the conductive sheet or the corona electrode.

In this state, the corona electrode moves along (scans) a top surface of the piezoelectric composite 10 in a direction perpendicular to the extending direction while maintaining a predetermined gap, thereby performing the polarization processing of the piezoelectric composite 10.

For example, as schematically shown in FIG. 3A, an electroacoustic converter film 16a is obtained by providing the electrode layer 18 on opposite surfaces of the piezoelectric composite 10 according to the present invention. Alternatively, as schematically shown in FIG. 3B, an electroacoustic converter film 16b is obtained by further providing the protective layer 20 on the surfaces of the electrode layers 18.

Examples of a material for forming the electrode layer 18 include copper, aluminum, gold, silver, platinum, and indium tin oxide.

In addition, preferable examples of a material for forming the protective layer 20 which can be used include polyethylene terephthalate (PET), polypropylene (PP), polystyrene (PS), polycarbonate (PC), polyphenylene sulfide (PPS), polymethyl methacrylate (PMMA), polyether imide (PEI), polyimide (PI), polyethylene naphthalate (PEN), triacetyl cellulose (TAC), and a cyclic olefin resin. In a case where the protective layer 20 is extremely thin and handleability is poor, optionally, a protective layer 20 equipped with a separator (peelable support) may be used.

The electroacoustic converter film 16a or the electroacoustic converter film 16b can generate (reproduce) a sound using vibration in response to an electric signal or can convert vibration, which is generated by a sound, into an electric signal in various acoustic devices (acoustic equipments), for example, a pickup used in a musical instrument such as a speaker, a microphone, or a guitar.

In particular, the piezoelectric characteristics or flexibility of the piezoelectric composite 10 according to the present invention can be suitably used for a flexible speaker such as a speaker for a flexible display.

Hereinabove, the piezoelectric polymer composite (piezoelectric composite) according to the present invention has been described above. However, the present invention is not limited to the above-described examples, and various improvements and modifications can be made within a range not departing from the scope of the present invention.

### EXAMPLES

Hereinafter, the piezoelectric polymer composite (piezoelectric composite) according to the present invention will be described in more detail using specific examples of the present invention.

### Example 1

As starting materials, oxide powders of Pb, Zr, and Ti as major components were prepared and were mixed with each other through a wet process using a ball mill for 12 hours. At this time, regarding the amounts of the respective oxides, Zr=0.52 mol and Ti=0.48 mol with respect to Pb=1 mol.

This raw material mixed powder was put into a crucible, was fired at 1000° C. for 5 hours, and was crushed using a ball mill for 3 minutes. As a result, the piezoelectric particles 14 were prepared.

The particle size distribution of the prepared piezoelectric particles 14 was measured using a laser scattering particle size analyzer (Microtrac MT3300, manufactured by Nikkiso Co., Ltd.). As a result, the median size (D50) was 3.6 μm, the proportion of particles having a particle size of 1 μm or less (V<1 μm) was 5.3 vol %, and a maximum value was shown at a particle size of 19.8 μm which was the median size or more.

In addition, in this example, the thickness of the piezoelectric composite 10 (hereinafter, also referred to as “set thickness”) was set as 39 μm, the proportion of particles having a particle size which was 0.25 times or more the set thickness (V>0.25T) was 17.7 vol %, and particles having a particle size of the set thickness or more were not recognized.

300 parts by mass of the prepared piezoelectric particles 14, 30 parts by mass of cyanoethylated polyvinyl alcohol (CR-V, manufactured by Shin-Etsu Chemical Co., Ltd.), and 70 parts by mass of dimethylfonnamide (DMF) were mixed with each other were kneaded using a propeller mixer (rotating speed: 2000 rpm). As a result, a paint for preparing the piezoelectric composite 10 was prepared.

Using a slide coater, this paint was applied to an aluminum plate having a thickness of 300 μm. The coating thickness was set such that the thickness of the dried coating film was 39 μm which was the set thickness.

Next, by heating the paint on a hot plate at 120° C. for 1 hour, DMF was evaporated and the paint was dried. As a result, the piezoelectric composite 10 having a thickness of 39 μm was prepared on the aluminum plate.

Calendering was performed on the piezoelectric composite 10 at a roll temperature of 80° C. and at a pressure of 0.3 MPa. Next, by connecting a DC power supply was between a wire-shaped corona electrode and the aluminum plate, the corona electrode is caused to scan a top surface of the piezoelectric composite while applying a DC voltage of 6 kV between the corona electrode and the aluminum plate, thereby performing the polarization processing of the piezoelectric composite 10. During the polarization processing, the piezoelectric composite was heated to 100° C.

An aluminum electrode having a diameter of 15 mm and a thickness of 0.5 μm was formed by vacuum deposition on a surface of the piezoelectric composite 10 having undergone thee polarization processing.

Further, the value of the piezoelectric characteristics d₃₃ (piezoelectric constant d₃₃) of the piezoelectric composite 10 was measured using a d₃₃ meter (PM-300, manufactured by Piezotest Pte Ltd.). The measurement of the piezoelectric characteristics d₃₃ was performed under conditions of frequency: 110 Hz, clamping force: 10 N, and dynamic force: 0.25 N.

As a result, the value of the piezoelectric characteristics d₃₃ of the piezoelectric composite 10 was 89 pC/N.

The above results are shown in a table shown below.

### Example 2

The piezoelectric particles 14 were prepared using the same method as in Example 1, except that the time of cracking using a ball mill was changed 10 minutes.

The particle size distribution of the obtained piezoelectric particles 14 was measured using the same method as in Example 1. As a result, the median size (D50) was 3.5 μm, the proportion of particles having a particle size of 1 μm or less (V<1 μm) was 7.5 vol %, and a maximum value was shown at a particle size of 15.0 μm which was the median size or more.

In addition, in this example, the set thickness was 19 μm, the proportion of particles having a particle size which was 0.25 times or more the set thickness (V>0.25T) was 15.6 vol %, and particles having a particle size of the set thickness or more were not recognized.

Next, a paint including the piezoelectric particles 14 was prepared using the same method as in Example 1.

As in the case of Example 1, using a slide coater, this paint was applied to an aluminum plate having a thickness of 300 μm. The coating thickness was set such that the thickness of the dried coating film was 19 μm which was the set thickness.

Next, by heating the paint on a hot plate at 120° C. for 1 hour, DMF was evaporated and the paint was dried. As a result, the piezoelectric composite 10 having a thickness of 19 μm was prepared on the aluminum plate. Further, using the same method as in Example 1, calendering and polarization processing were performed.

Using the same method as in Example 1, an aluminum electrode was formed on the obtained piezoelectric composite 10, and the piezoelectric characteristics of the piezoelectric composite 10 were measured.

As a result, the value of the piezoelectric characteristics d₃₃ of the piezoelectric composite 10 was 86 pC/N.

The above results are shown in the table shown below.

### Example 3

The piezoelectric particles 14 were prepared using the same method as in Example 1, except that the time of cracking using a ball mill was changed 20 minutes.

The particle size distribution of the obtained piezoelectric particles 14 was measured using the same method as in Example 1. As a result, the median size (D50) was 3.2 μm, the proportion of particles having a particle size of 1 μm or less (V<1 μm) was 7.8 vol %, and a maximum value was shown at a particle size of 8.2 μm which was the median size or more.

In addition, in this example, the set thickness was 11 μm, the proportion of particles having a particle size which was 0.25 times or more the set thickness (V>0.25T) was 28 vol %, and particles having a particle size of the set thickness or more were not recognized.

Next, a paint including the piezoelectric particles 14 was prepared using the same method as in Example 1.

As in the case of Example 1, using a slide coater, this paint was applied to an aluminum plate having a thickness of 300 μm. The coating thickness was set such that the thickness of the dried coating film was 11 μm which was the set thickness.

Next, by heating the paint on a hot plate at 120° C. for 1 hour, DMF was evaporated and the paint was dried. As a result, the piezoelectric composite 10 having a thickness of 11 μm was prepared on the aluminum plate. Further, using the same method as in Example 1, calendering and polarization processing were performed.

Using the same method as in Example 1, an aluminum electrode was formed on the obtained piezoelectric composite 10, and the piezoelectric characteristics of the piezoelectric composite 10 were measured.

As a result, the value of the piezoelectric characteristics d₃₃ of the piezoelectric composite 10 was 85 pC/N.

The above results are shown in the table shown below.

### Example 4

The piezoelectric particles 14 were prepared using the same method as in Example 1, except that the time of cracking using a ball mill was changed 4 hours.

The particle size distribution of the obtained piezoelectric particles 14 was measured using the same method as in Example 1. As a result, the median size (D50) was 3.2 μm, the proportion of particles having a particle size of 1 μm or less (V<1 μm) was 7.9 vol %, and a maximum value was not shown at a particle size of the median size or more.

In addition, in this example, the set thickness was 40 μm, the proportion of particles having a particle size which was 0.25 times or more the set thickness (V>0.25T) was 10.5 vol %, and particles having a particle size of the set thickness or more were not recognized.

Next, a paint including the piezoelectric particles 14 was prepared using the same method as in Example 1.

As in the case of Example 1, using a slide coater, this paint was applied to an aluminum plate having a thickness of 300 μm. The coating thickness was set such that the thickness of the dried coating film was 40 μm which was the set thickness.

Next, by heating the paint on a hot plate at 120° C. for 1 hour, DMF was evaporated and the paint was dried. As a result, the piezoelectric composite 10 having a thickness of 40 μm was prepared on the aluminum plate. Further, using the same method as in Example 1, calendering and polarization processing were performed.

Using the same method as in Example 1, an aluminum electrode was formed on the obtained piezoelectric composite 10, and the piezoelectric characteristics of the piezoelectric composite 10 were measured.

As a result, the value of the piezoelectric characteristics d₃₃ of the piezoelectric composite 10 was 76 pC/N.

The above results are shown e table shown below.

### Comparative Example 1

Piezoelectric particles were prepared using the same method as in Example 1, except that the firing time was changed 8 hours.

The particle size distribution of the obtained piezoelectric particles was measured using the same method as in Example 1. As a result, the median size (D50) was 8.2 μm, the proportion of particles having a particle size of 1 μm or less (V<1 μm) was 5 vol %, and a maximum value was not shown at a particle size of the median size or more.

In addition, in this example, the set thickness was 42 μm, the proportion of particles having a particle size which was 0.25 times or more the set thickness (V>0.25T) was 33 vol %, and particles having a particle size of the set thickness or more were not recognized.

Next, a paint including the piezoelectric particles was prepared using the same method as in Example 1.

As in the case of Example 1, using a slide coater, this paint was applied to an aluminum plate having a thickness of 300 μm. The coating thickness was set such that the thickness of the dried coating film was 42 μm which was the set thickness.

Next, by heating the paint on a hot plate at 120° C. for 1 hour, DMF was evaporated and the paint was dried. As a result, the piezoelectric composite having a thickness of 42 μm was prepared on the aluminum plate. Further, using the same method as in Example 1, calendering and polarization processing were performed.

Using, the same method as in Example 1, an aluminum electrode was formed on the obtained piezoelectric composite, and the piezoelectric characteristics of the piezoelectric composite were measured.

As a result, the value of the piezoelectric characteristics d₃₃ of the piezoelectric composite was 50 pC/N.

The above results are shown in the table shown below.

### Comparative Example 2

Piezoelectric particles were prepared using the same method as in Example 1, except that the time of cracking using a ball mill was changed 24 hours.

The particle size distribution of the obtained piezoelectric particles was measured using the same method as in Example 1. As a result, the median size (D50) was 3 μm, the proportion of particles having a particle size of 1 μm or less (V<1 μm) was 15 vol %, and a maximum value was not shown at a particle size of the median size or more.

In addition, in this example, the set thickness was 37 μm, the proportion of particles having a particle size which was 0.25 times or more the set thickness (V>0.25T) was 4.9 vol %, and particles having a particle size of the set thickness or more were not recognized.

Next, a paint including the piezoelectric particles was prepared using the same method as in Example 1.

As in the case of Example 1, using a slide coater, this paint was applied to an aluminum plate having a thickness of 300 μm. The coating thickness was set such that the thickness of the dried coating film was 37 μm which was the set thickness.

Next, by heating the paint on a hot plate at 120° C. for 1 hour, DMF was evaporated and the paint was dried. As a result, the piezoelectric composite having a thickness of 37 μm was prepared on the aluminum plate. Further, using the same method as in Example 1, calendering and polarization processing were performed.

Using the same method as in Example 1, an aluminum electrode was formed on the obtained piezoelectric composite, and the piezoelectric characteristics of the piezoelectric composite were measured.

As a result, the value of the piezoelectric characteristics d₃₃ of the piezoelectric composite was 45 pC/N.

The above results are shown in the table shown below.

TABLE 1

| | | | | | | Piezoelectric |
|---|---|---|---|---|---|---|
| | | | | | Maximum | Characteristics |
| | Thickness | D50 | V < 1 μm | V > 0.25 T | Value | (d33) |
| | [μm] | [μm] | [vol %] | [vol %] | [μm] | [pC/N] |
| Example 1 | 39 | 3.6 | 5.3 | 17.7 | 19.8 | 89 |
| Example 2 | 19 | 3.5 | 7.5 | 15.6 | 15 | 86 |
| Example 3 | 11 | 3.2 | 7.8 | 28 | 8.2 | 85 |
| Example 4 | 40 | 3.2 | 7.9 | 10.5 | None | 76 |
| Comparative | 42 | 8.2 | 5 | 33 | None | 50 |
| Example 1 | | | | | | |
| Comparative | 37 | 3 | 15 | 4.9 | None | 45 |
| Example 2 | | | | | | |

All of the piezoelectric particles were lead zirconate titanate particles

As can be seen from the above table, in the piezoelectric composite 10 according to the present invention in which the piezoelectric particles 14 include 5 vol % to 30 vol % of particles having a particle size which is 0.25 times to 1 time the thickness T, the transmission efficiency of vibration energy is high due to coarse particles, the packing density of the piezoelectric particles 14 is high by fine particles entering into gaps between the coarse particles, and satisfactory piezoelectric characteristics are exhibited due to a synergistic effect of high transmission efficiency of vibration energy and high packing density of the piezoelectric particles. In addition, it can be seen that, by using particles in which the particle size distribution of the piezoelectric particles 14 has a maximum value at a particle size of the median size or more, the piezoelectric composite 10 has more satisfactory piezoelectric characteristics.

Further, in the piezoelectric composite 10 having satisfactory piezoelectric characteristics, the condition that the piezoelectric particles 14 include 5 vol % to 30 vol % of piezoelectric particles having a particle size which is 0.25 times to 1 time the thickness T is satisfied, the amount of the particles having a particle size of 1 μm or less is 10 vol % or lower, and the median size is in a range of (1+the thickness of the piezoelectric polymer composite×0.05) to (1+the thickness of the piezoelectric polymer composite×0.3).

On the other hand, in the piezoelectric composite according to Comparative Example 1 in which the amount of the piezoelectric particles which is 0.25 times to 1 time the thickness T is 33 vol %, it is considered that the volume density is not sufficient due to an excess amount of coarse particles. In addition, in the piezoelectric composite according to Comparative Example 2 in which the amount of the piezoelectric particles which is 0.25 times to 1 time the thickness T is 4.9 vol %, it is considered that the transmission efficiency of vibration energy is not sufficient due to a small amount of coarse particles. In both of the piezoelectric composite according to Comparative Examples, the piezoelectric characteristics are lower than that of the piezoelectric composite according to the present invention.

As can be seen from the above results, the effects of the present invention are obvious.

### EXPLANATION OF REFERENCES

10: piezoelectric (polymer) composite
12: matrix
14: piezoelectric particle
16a, 16b: electroacoustic converter film
18: electrode layer
20: protective layer

What is claimed is:

1. A piezoelectric polymer composite comprising:
a matrix that is formed of a polymer material; and
piezoelectric particles that are dispersed in the matrix,
wherein the piezoelectric particles include 5 vol % to 30 vol % of particles having a particle size which is 0.25 times to 1 time a thickness of the piezoelectric polymer composite.

2. The piezoelectric polymer composite according to claim 1,
wherein a particle size distribution of the piezoelectric particles has a maximum value at a particle size in a range from a median size (D50) to the thickness of the piezoelectric polymer composite.

3. The piezoelectric polymer composite according to claim 1,
wherein an amount of particles having a particle size of 1 μm or less in the piezoelectric particles is 10 vol % or lower.

4. The piezoelectric polymer composite according to claim 1,
wherein the median size (D50) of the piezoelectric particles is (1+the thickness of the piezoelectric polymer composite×0.05) to (1+the thickness of the piezoelectric polymer composite×0.3).

5. The piezoelectric polymer composite according to claim 1,
wherein the piezoelectric particles are lead zirconate titanate particles.

6. The piezoelectric polymer composite according to claim 1,
wherein the matrix is formed of a polymer material having viscoelasticity at normal temperature.
